(19) United States
(12) Patent Application Publication
(10) Pub. No.: US 2024/0321908 A1
(43) Pub. Date: Sep. 26, 2024

(54) PIXEL STRUCTURE AND MANUFACTURING METHOD OF PIXEL STRUCTURE

(71) Applicant: E Ink Holdings Inc., Hsinchu (TW)

(72) Inventors: Kun Hsiang Chiang, Hsinchu (TW); Kuo-Hsing Cheng, Hsinchu (TW); Liu Chung Lee, Hsinchu (TW)

(73) Assignee: E Ink Holdings Inc., Hsinchu (TW)

(21) Appl. No.: 18/444,771

(22) Filed: Feb. 19, 2024

Related U.S. Application Data
(60) Provisional application No. 63/453,163, filed on Mar. 20, 2023.

(51) Int. Cl. H01L 27/12

(52) U.S. Cl. CPC H01L 27/1248; H01L 27/1288

(57) ABSTRACT

A pixel structure including a substrate, an active device, a planarization layer, a pixel electrode, and a patterned protection layer is provided. The active device is disposed on the substrate. The planarization layer is disposed on the substrate and covers the active device. The pixel electrode is disposed on the planarization layer and electrically connected to the active device. The patterned protection layer is disposed on the planarization layer and laterally surrounds the pixel electrode, and both the patterned protection layer and the pixel electrode are in contact with the planarization layer.

### CROSS-REFERENCE TO RELATED APPLICATION

This application claims the priority benefit of U.S. Provisional application Ser. No. 63/453,163, filed on Mar. 20, 2023. The entirety of the above-mentioned patent application is hereby incorporated by reference herein and made a part of this specification.

### BACKGROUND

### Technical Field

The disclosure relates to an electronic device and a manufacturing method of the electronic device, and in particular to a pixel structure and a manufacturing method of the pixel structure.

### Description of Related Art

In the field of display devices, in order to provide more functions and/or circuit transmission requirements, it is necessary to integrate many kinds of elements, film layers, etc. on the same substrate. In the process of integrating multiple components, film layers, etc., it is necessary to ensure that the existing components are not damaged during the manufacturing process in order to achieve an ideal yield.

### SUMMARY

The disclosure provides a pixel structure that can ensure the quality of integrating multiple elements on the same substrate.

The disclosure provides a manufacturing method of a pixel structure, which can improve the manufacturing yield of integrating multiple elements on the same substrate.

A pixel structure of an embodiment of the disclosure includes a substrate, an active device, a planarization layer, a pixel electrode, and a patterned protection layer. The active device is disposed on the substrate. The planarization layer is disposed on the substrate and covers the active device. The pixel electrode is disposed on the planarization layer and electrically connected to the active device. The patterned protection layer is disposed on the planarization layer and laterally surrounds the pixel electrode, and both the patterned protection layer and the pixel electrode are in contact with the planarization layer.

In an embodiment of the disclosure, the patterned protection layer has an opening, and the pixel electrode overlaps an area of the opening.

In an embodiment of the disclosure, an outline of the opening is substantially aligned with an outline of the pixel electrode.

In an embodiment of the disclosure, a material of the patterned protection layer includes an inorganic insulation material.

In an embodiment of the disclosure, a material of the patterned protection layer includes silicon nitride.

In an embodiment of the disclosure, the patterned protection layer partially overlaps a periphery of the pixel electrode.

In an embodiment of the disclosure, a material of the patterned protection layer includes an organic insulation material.

In an embodiment of the disclosure, the pixel electrode and the patterned protection layer completely cover the planarization layer.

In an embodiment of the disclosure, the pixel structure further includes a functionality layer. The functionality layer is disposed on the substrate. The functionality layer and the active device are positioned on two opposite sides of the substrate.

A manufacturing method of a pixel structure of an embodiment of the disclosure includes the following, but is not limited thereto. An active device is formed on a substrate. A planarization layer is formed on the substrate to cover the active device. A pixel electrode is formed on the planarization layer by using a common photomask. A patterned protection layer is formed on the planarization layer by using the common photomask, in which the patterned protection layer laterally surrounds the pixel electrode.

In an embodiment of the disclosure, a method of forming the pixel electrode includes the following. A conductive material layer and a first photoresist layer are formed on the planarization layer. The first photoresist layer is patterned into a first photoresist pattern by using the common photomask. The conductive material layer is patterned into the pixel electrode by using the first photoresist pattern as a mask.

In an embodiment of the disclosure, a method of forming the patterned protection layer includes the following. An insulation material layer and a second photoresist layer is formed on the planarization layer. The second photoresist layer is patterned into a second photoresist pattern by using the common photomask. The insulation material layer is patterned into the patterned protection layer by using the second photoresist pattern as a mask.

In an embodiment of the disclosure, the first photoresist layer is a positive photoresist and the second photoresist layer is a negative photoresist.

In an embodiment of the disclosure, the first photoresist pattern and the second photoresist pattern are complementary patterns.

In an embodiment of the disclosure, a method of forming the patterned protection layer includes the following. A photosensitive insulation material layer is formed on the planarization layer. The photosensitive insulation material layer is patterned into the patterned protection layer by using the common photomask.

In an embodiment of the disclosure, the first photoresist layer is a positive photoresist and the photosensitive insulation material layer is a negative photoresist.

In an embodiment of the disclosure, the method of forming the patterned protection layer further includes a baking operation to form a slope on an edge of the patterned protection layer.

In an embodiment of the disclosure, the manufacturing method of the pixel structure further includes the following. A functionality layer is formed on the substrate. The functionality layer and the active device are positioned on two opposite sides of the substrate.

In an embodiment of the disclosure, the manufacturing method of the pixel structure further includes the following. A contact hole is formed in the planarization layer, so that the pixel electrode is electrically connected to the active device through the contact hole.

In an embodiment of the disclosure, a material of the planarization layer includes a positive photoresist.

Based on the above, in the pixel structure and the manufacturing method of the pixel structure according to embodiments of the disclosure, the patterned protection layer is disposed around the pixel electrode, so that the patterned protection layer and the pixel electrode cover the planarization layer. In some embodiments, when manufacturing other elements or film layers on the substrate, the disposition of the patterned protection layer and the pixel electrode can prevent the planarization layer from being damaged, thereby helping improve the yield and ensure product quality.

### BRIEF DESCRIPTION OF THE DRAWINGS

FIG. 1 to FIG. 7 schematically illustrate a manufacturing process of a pixel structure according to an embodiment of the disclosure.

FIG. 8 to FIG. 9 schematically illustrate a manufacturing process of a pixel structure according to another embodiment of the disclosure.

### DESCRIPTION OF THE EMBODIMENTS

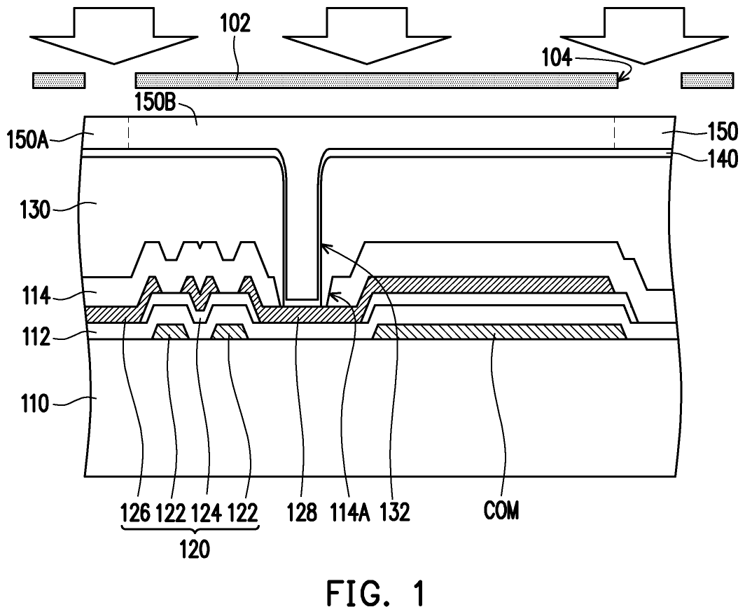

FIG. 1 illustrates a part of operations of a manufacturing method of a pixel structure. In FIG. 1, the manufacturing method of the pixel structure includes the following. An active device 120 is formed on a substrate 110. The active device 120 may include a gate 122, a semiconductor layer 124, a first source/drain 126, and a second source/drain 128. In some embodiments, the gate 122 may be formed by patterning a first conductive layer formed on the substrate 110, and materials thereof include metal, metal oxide, metal nitride, metal oxynitride, or a combination thereof. In addition to forming the gate 122, the first conductive layer may also form a common electrode COM. The semiconductor layer 124 may be formed by patterning semiconductor material layers, and materials thereof include crystalline silicon, amorphous silicon, polysilicon, oxide semiconductors, organic semiconductors, etc., in which the oxide semiconductors may include Indium-Gallium-Zinc Oxide (IGZO), Zinc Oxide (ZnO), Tin Oxide (SnO), Indium-Zinc Oxide (IZO), Gallium-Zinc Oxide (GZO), Zinc-Tin Oxide (ZTO), or Indium-Tin Oxide (ITO), but is not limited thereto. The first source/drain 126 and the second source/drain 128 may be formed by patterning a second conductive layer formed on the substrate 110, and materials thereof include metal, metal oxide, metal nitride, metal oxynitride, or a combination thereof. In addition, in order to separate different conductive layers, a gate insulation layer 112 and a passivation layer 114 are formed on the substrate 110, in which the gate insulation layer 112 is disposed between the gate 122 and the semiconductor layer 124, and the passivation layer 114 covers the first source/drain 126 and the second source/drain 128. The active device 120 as a whole may be disposed between the substrate 110 and the passivation layer 114, but is not limited thereto. Materials of the gate insulation layer 112 and the passivation layer 114 may include inorganic insulation materials, organic insulation materials, or combinations thereof. In some embodiments, the gate insulation layer 112 and the passivation layer 114 may be formed comprising a stack of multiple layers of insulation materials. In some embodiments, the inorganic insulation material includes silicon oxide, silicon oxynitride, silicon nitride, etc., or a combination thereof. The organic insulation material includes polymer materials such as polyimide resin, epoxy resin, or acrylic resin.

In FIG. 1, the manufacturing method of the pixel structure further includes the following. A planarization layer 130 is formed on the substrate 110 to cover the active device 120. Materials of the planarization layer 130 may include organic insulation materials, such as polymer materials such as polyimide resin, epoxy resin, or acrylic resin. In some embodiments, the material of the planarization layer 130 includes positive photoresist. A method of forming the planarization layer 130 may include the following. An organic insulation material is formed on the substrate 110, and the organic insulation material is cured to form the planarization layer 130. The method of forming the planarization layer 130 may also include the following. A contact hole 132 is formed in the planarization layer 130, in which an area of the contact hole 132 overlaps a part of the second source/drain 128, so that the planarization layer 130 does not completely shield (cover) the active device 120. In some embodiments, the passivation layer 114 may have an opening 114A, and the contact hole 132 corresponds to the opening 114A.

The manufacturing method of the pixel structure in FIG. 1 also includes the following. A conductive material layer 140 and a first photoresist layer 150 are formed on the substrate 110. The conductive material layer 140 and the first photoresist layer 150 are sequentially disposed on the planarization layer 130, and the conductive material layer 140 may be filled into the contact hole 132 to contact the second source/drain 128. The material of the conductive material layer 140 may include transparent conductive materials, such as metal oxides such as indium tin oxide, indium zinc oxide, aluminum tin oxide, aluminum zinc oxide, or indium germanium zinc oxide, but not limited thereto.

In FIG. 1, a common photomask 102 may be used to perform an exposure operation on the first photoresist layer 150. The common photomask 102 has a plurality of light transmitting openings 104 to allow the first photoresist layer 150 to be partially illuminated by an exposure light. In some embodiments, the first photoresist layer 150 is, for example, a positive photoresist, so an exposed portion 150A of the first photoresist layer 150 may undergo reactions such as decomposition and have different properties from an unexposed portion 150B.

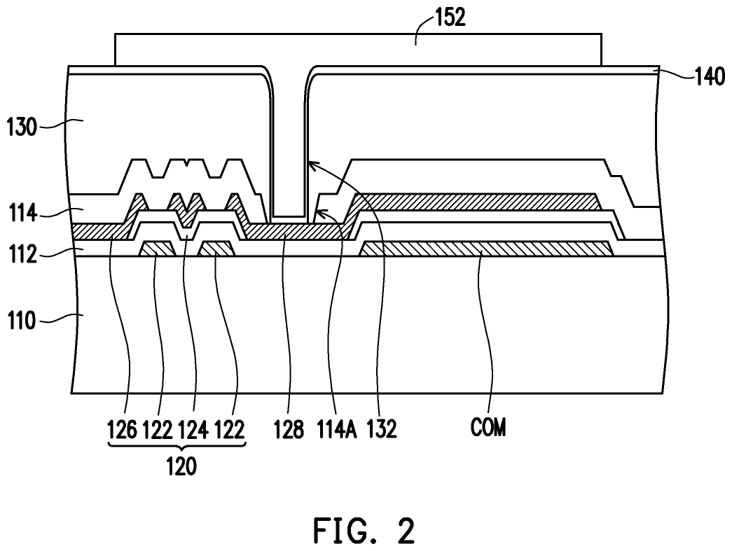

Next, as shown in FIG. 2, after a developing operation, the exposed portion 150A of the first photoresist layer 150 may be removed, while the unexposed portion 150B remains, so that the first photoresist layer 150 is patterned into a first photoresist pattern 152. In some embodiments, after the developing operation, a further heating operation may be optionally performed to completely cure the first photoresist pattern 152. At this time, a portion of the conductive material layer 140 originally shielded by the exposed portion 150A of the first photoresist layer 150 may be exposed.

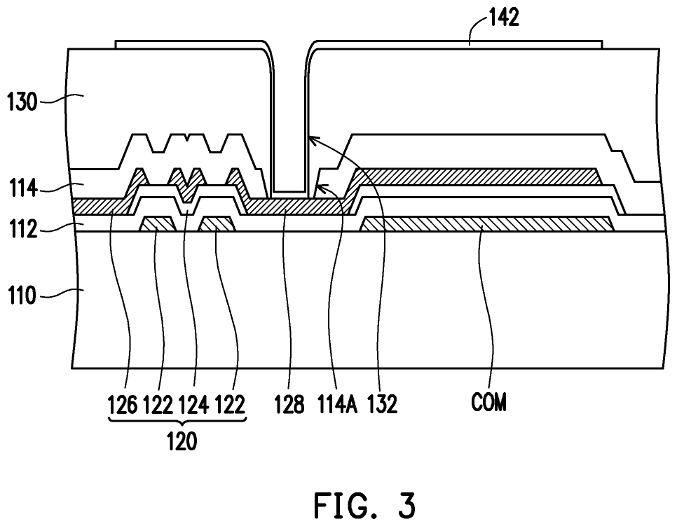

Next, as shown in FIG. 3, using the first photoresist pattern 152 in FIG. 2 as a mask, the conductive material layer 140 is patterned and the first photoresist pattern 152 is removed, thereby forming a pixel electrode 142. An outline of the pixel electrode 142 may be approximately the same as the first photoresist pattern 152 in FIG. 2. At the same time, the planarization layer 130 around the pixel electrode 142 is exposed. An operation of patterning the conductive material layer 140 is implemented, for example, by an etching process. For example, dry etching may be used to pattern the conductive material layer 140 into the pixel electrode 142.

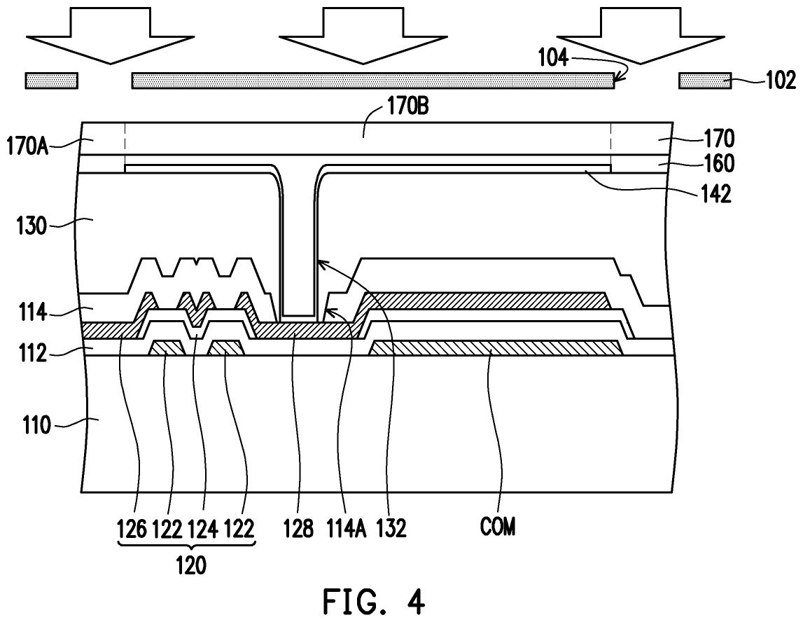

Next, as shown in FIG. 4, an insulation material layer 160 and a second photoresist layer 170 are formed on the planarization layer 130. The insulation material layer 160 may cover the pixel electrode 142 and a part of the planarization layer 130 not covered by the pixel electrode 142. In other words, the insulation material layer 160 may approximately cover an entire area of the substrate 110. The second photoresist layer 170 covers the entire insulation material layer 160. In this embodiment, the material of the insulation material layer includes inorganic insulation materials, such as silicon oxide, silicon oxynitride, silicon nitride, etc. or combinations thereof. The second photoresist layer 170 is, for example, a negative photoresist.

In an operation in FIG. 4, the manufacturing method of the pixel structure further includes the following. The second photoresist layer 170 is patterned by using the common photomask 102. As shown in FIG. 4, the common photomask 102 is the same as the common photomask 102 used to pattern the first photoresist layer 150 in FIG. 1. The common photomask 102 has the plurality of light transmitting openings 104, so that the portion of the second photoresist layer 170 corresponding to the light transmitting openings 104 is exposed to become an exposed portion 170A by using an exposure process. Since the second photoresist layer 170 is a negative photoresist, the exposed portion 170A of the second photoresist layer 170 undergoes crosslinking and other reactions, so that the exposed portion 170A and the unexposed portion 170B of the second photoresist layer 170 have different properties.

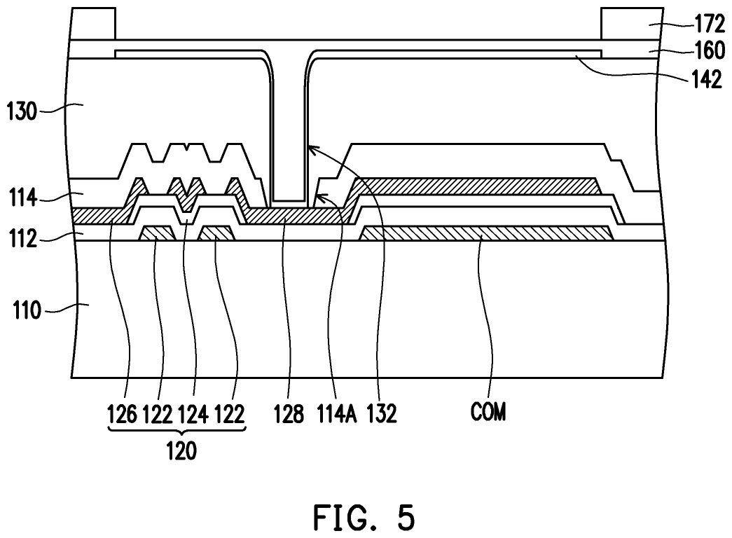

Next, a developing operation is performed so that the exposed portion 170A of the second photoresist layer 170 remains and the unexposed portion 170B is removed to form a second photoresist pattern 172 shown in FIG. 5. In other words, the operations in FIG. 4 and FIG. 5 include using the common photomask 102 to pattern the second photoresist layer 170 into the second photoresist pattern 172. In this embodiment, the first photoresist layer 150 (shown in FIG. 1) forming the first photoresist pattern 152 is a positive photoresist, and the second photoresist layer 170 (shown in FIG. 4) forming the second photoresist pattern 172 is a negative photoresist, and the first photoresist layer 150 and the second photoresist layer 170 use the same common photomask 102 for patterning, so the first photoresist pattern 152 and the second photoresist pattern 172 are complementary patterns.

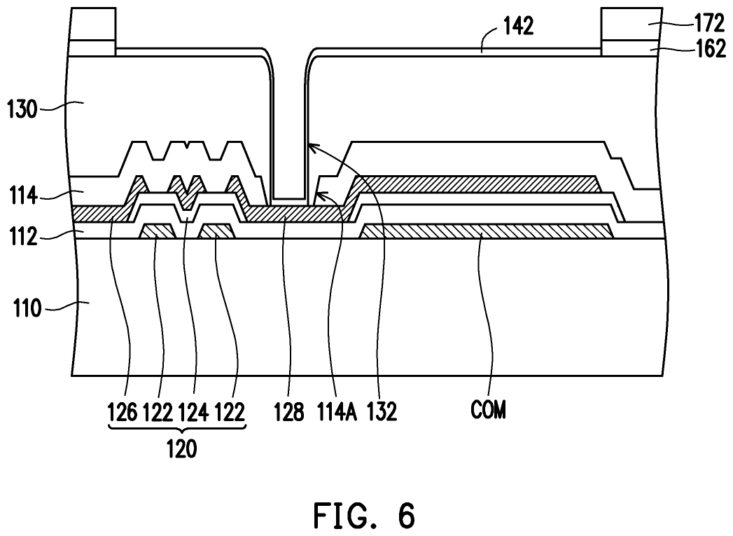

As shown in FIG. 6, after the second photoresist pattern 172 is formed, the insulation material layer 160 is patterned into a patterned protection layer 162 by using the second photoresist pattern 172 as a mask. For clarity, a thickness of the insulation material layer 160 in FIG. 4 and FIG. 5 is shown to be thicker than a thickness of the patterned protection layer 162 in FIG. 6, but in fact, in the operations in FIG. 4 to FIG. 6, the thicknesses of the insulation material layer 160 and the patterned protection layer 162 are approximately the same. In some embodiments, the thickness of the patterned protection layer 162 is thicker than the pixel electrode 142. An outline of the patterned protection layer 162 may be approximately the same as the second photoresist pattern 172. Since the outlines of the first photoresist pattern 152 and the second photoresist pattern 172 are complementary, the outline of the patterned protection layer 162 and the outline of the pixel electrode 142 may also be approximately complementary.

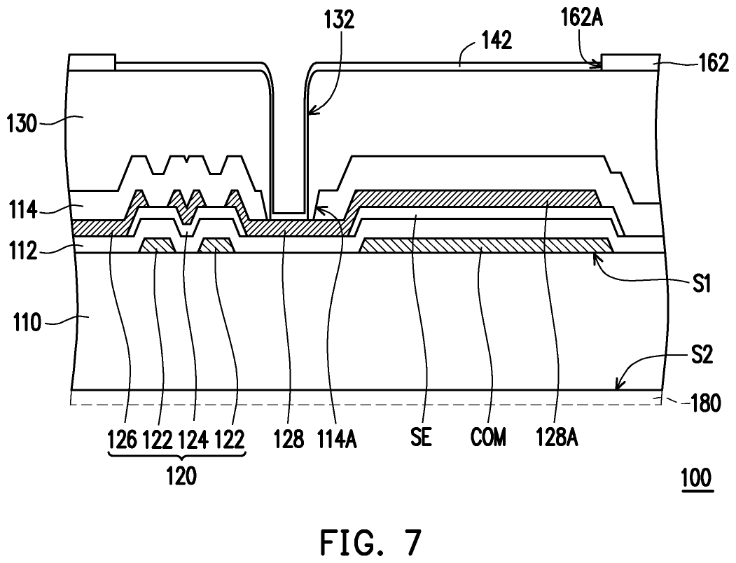

Next, the second photoresist pattern 172 is removed to obtain a pixel structure 100 shown in FIG. 7. In some embodiments, after the patterned protection layer 162 is completed, a functionality layer 180 may be optionally further formed on the substrate 110, in which the functionality layer 180 and the active device 120 are positioned on two opposite sides of the substrate 110. That is to say, the active device 120, the pixel electrode 142, and the components and film layers described in FIG. 1 to FIG. 6 are all disposed on a first surface S1 of the substrate 110, and the functionality layer 180 may be disposed on a second surface S2 of the substrate 110. In some embodiments, after the patterned protection layer 162 is completed, the substrate 110 may be turned upside down so that the second surface S2 of the substrate 110 faces up, so as to make the functionality layer 180 on the second surface S2. The functionality layer 180 may include an electrode layer, a wiring layer, an optical film layer, an insulation layer, or a combination thereof. In this way, besides the active device 120 and the pixel electrode 142, the pixel structure 100 also includes the functionality layer 180, which can realize multiple functions.

In FIG. 7, the pixel structure 100 includes the substrate 110, the active device 120, the planarization layer 130, the pixel electrode 142, and the patterned protection layer 162. The active device 120, the planarization layer 130, the pixel electrode 142, and the patterned protection layer 162, for example, may be manufactured sequentially on the first surface S1 of the substrate 110, and may be manufactured with reference to the manufacturing process shown in FIG. 1 to FIG. 6, but is not limited thereto. The active device 120 is disposed on the substrate 110, and the planarization layer 130 is disposed on the substrate 110 and covers the active device 120. The pixel electrode 142 is disposed on the planarization layer 130 and electrically connected to the active device 120. The patterned protection layer 162 is disposed on the planarization layer 130 and laterally surrounds the pixel electrode 142, and both the patterned protection layer 162 and the pixel electrode 142 are in contact with the planarization layer 130.

The active device 120 mainly includes the gate 122, the semiconductor layer 124, the first source/drain 126, and the second source/drain 128. The first source/drain 126 and the second source/drain 128 contact different parts of the semiconductor layer 124, and the gate 122 overlaps the part between the first source/drain 126 and the second source/drain 128 of the semiconductor layer 124. In order to make individual conductive film layers conduct independently, the pixel structure 100 further includes the gate insulation layer 112 disposed between the gate 122 and the semiconductor layer 124 and the passivation layer 114 covering the first source/drain 126 and the second source/drain 128. The planarization layer 130 is disposed on the passivation layer 114. In addition, the pixel structure 100 may further include a common electrode COM at the same layer as the gate 122. The common electrode COM may overlap an extension portion 128A of the second source/drain 128 to form a storage capacitor. The pixel structure 100 may also optionally include a semiconductor pattern SE of the same layer as the semiconductor layer 124, and the semiconductor pattern SE may overlap the common electrode COM and contact the extension portion 128A.

The planarization layer 130 has the contact hole 132 extending to the second source/drain 128, and the pixel electrode 142 is disposed conforming to the configuration of the contact hole 132 and contacts the second source/drain 128, thereby realizing the electrical connection between the pixel electrode 142 and the active device 120. The patterned protection layer 162 has an opening 162A, and the pixel electrode 142 overlaps an area of the opening 162A. As described in the above manufacturing process, the outlines of the pixel electrode 142 and the patterned protection layer 162 may be complementary, so an outline of the opening 162A is substantially aligned with an outline of the pixel electrode 142. In this way, the pixel electrode 142 and the patterned protection layer 162 may completely cover the planarization layer 130.

The patterned protection layer 162 may include inorganic insulation materials such as silicon oxide, silicon nitride, silicon oxynitride, or combinations thereof. In some embodiments, the thickness of the patterned protection layer 162 may range from 2,000 angstroms (Å) to 5,000 angstroms (Å). In some embodiments, the material of the patterned protection layer 162 includes silicon nitride, and the hardness of the patterned protection layer 162 may be greater than 4H.

In some embodiments, the pixel structure 100 further includes the functionality layer 180, and the functionality layer 180 and the active device 120 are positioned on two opposite sides of the substrate 110. When the functionality layer 180 is made on the second surface S2 of the substrate 110, the planarization layer 130 is completely covered, so the planarization layer 130 is less likely to be damaged during the process of making the functionality layer 180, which helps maintain the function of the planarization layer 130 and ensure the quality of the pixel structure 100. As far as the production process is concerned, the design that the planarization layer 130 is completely covered also helps improve the production yield of the pixel structure 100.

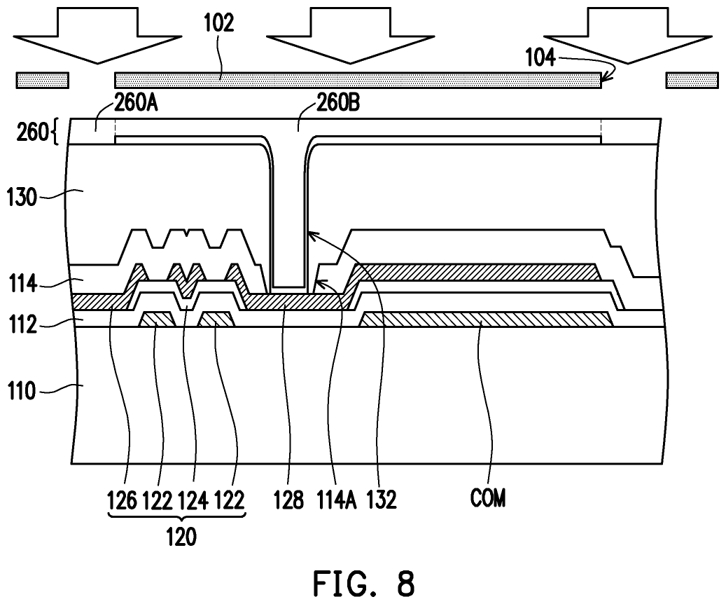

The operations shown in FIG. 8 are performed after the operations in FIG. 3 in another embodiment of the manufacturing method of the pixel structure. Therefore, the reference numerals recorded in FIG. 8 the same as in FIG. 3 may refer to FIG. 3 and the preceding operations in FIG. 1 to FIG. 2 to understand the elements represented therein. In FIG. 8, the manufacturing method of the pixel structure includes the following. A photosensitive insulation material layer 260 is formed on the planarization layer 130 and the photosensitive insulation material layer 260 is patterned by using the common photomask 102 described in FIG. 1. Specifically, the common photomask 102 has the plurality of light transmitting openings 104 to allow the photosensitive insulation material layer 260 to be partially irradiated by exposure light. The photosensitive insulation material layer 260 is a negative photoresist. An exposed portion 260A of the photosensitive insulation material layer 260 undergoes reactions such as crosslinking, so that the exposed portion 260A and an unexposed portion 260B of the photosensitive insulation material layer 260 have different properties.

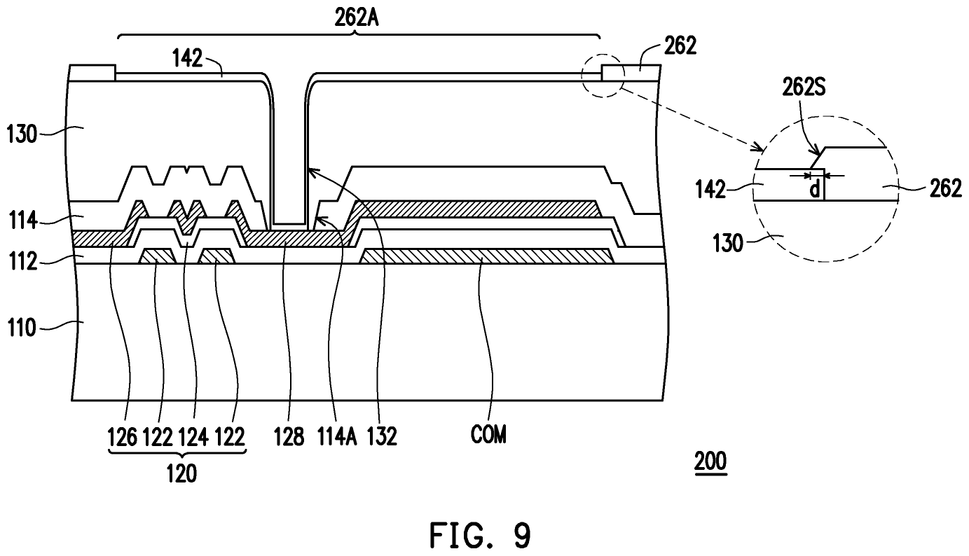

Next, a developing operation is performed, so that the exposed portion 260A of the photosensitive insulation material layer 260 remains and an unexposed portion 260B is removed and a patterned protection layer 262 shown in FIG. 9 is formed, thereby completing a pixel structure 200 of FIG. 9. In this embodiment, the photosensitive insulation material layer 260 may be patterned into the patterned protection layer 262 by using the common photomask 102 to form the pixel electrode 142. The outline of the patterned protection layer 262 may be complementary to the outline of the pixel electrode 142. In some embodiments, the method of forming the patterned protection layer 262 further includes a baking operation to form a slope 262S on an edge of the patterned protection layer 262. In some embodiments, the slope 262S may overlap the pixel electrode 142. Specifically, the patterned protection 262 may partially overlap a periphery of the pixel electrode 142. In some embodiments, the thickness of the patterned protection layer 262 may be about 2 microns, for example, 1 micron to 3 microns.

In FIG. 9, the pixel structure 200 includes the substrate 110, the active device 120, the planarization layer 130, the pixel electrode 142, and the patterned protection layer 262. The active device 120, the planarization layer 130, the pixel electrode 142, and the patterned protection layer 262, for example, may be disposed sequentially on the first surface S1 of the substrate 110, and may be manufactured with reference to the manufacturing process shown in FIG. 1 to FIG. 3 continuing to FIG. 8 to FIG. 9, but is not limited thereto. The active device 120 is disposed on the substrate 110, and the planarization layer 130 is disposed on the substrate 110 and covers the active device 120. The pixel electrode 142 is disposed on the planarization layer 130 and electrically connected to the active device 120. The patterned protection layer 262 is disposed on the planarization layer 130 and laterally surrounds the pixel electrode 142, and both the patterned protection layer 262 and the pixel electrode 142 are in contact with the planarization layer 130. The main difference between this embodiment and the embodiment of FIG. 7 is that a material of the patterned protection layer 262 is an organic insulation material, such as a negative photoresist. In addition, the patterned protection layer 262 has an opening 262A, and the pixel electrode 142 overlaps the area of the opening 262A, so that the pixel electrode 142 is not blocked by the patterned protection layer 262. In some embodiments, the edge of the patterned protection layer 262 has the slope 262S, and the patterned protection layer 262 may partially overlap the periphery of the pixel electrode 142, so that the patterned protection layer 262 and the pixel electrode 142 may completely cover the planarization layer 130. In some embodiments, the overlapping portion of the patterned protection layer 262 and the pixel electrode 142 may extend a distance d from the edge of the pixel electrode 142 toward the center of the pixel electrode 142, and the distance d may be approximately 0.5 μm.

In some embodiments, the pixel structure 200 may further include the functionality layer 180, and the functionality layer 180 and the active device 120 are positioned on two opposite sides of the substrate 110. The functionality layer 180 may include an electrode layer, a wiring layer, an optical film layer, an insulation layer, or a combination thereof. In this way, besides the active device 120 and the pixel electrode 142, the pixel structure 200 also includes the functionality layer 180, which can realize multiple functions. Since the patterned protection layer 262 and the pixel electrode 142 may completely cover the planarization layer 130, the planarization layer 130 and the layer between the planarization layer 130 and the substrate 110 are less likely to be damaged during the process of manufacturing the functionality layer 180. Therefore, the disposition of the patterned protection layer 262 is helpful to improve the manufacturing yield of the pixel structure 200 and ensure the quality of the pixel structure 200.

In summary, in the pixel structure of an embodiment of the disclosure, both the patterned protection layer and the pixel electrode are in contact with the planarization layer, and the patterned protection layer is disposed around the pixel electrode, so that the entire surface of the planarization layer is covered. Therefore, the planarization layer and the film layers between the planarization layer and the substrate are protected and are less likely to be damaged in other manufacturing processes. Therefore, the manufacturing method of the pixel structure in the embodiment of the disclosure has a good manufacturing yield and the pixel structure has ideal quality.

What is claimed is:

1. A pixel structure, comprising:
a substrate;
an active device disposed on the substrate;
a planarization layer disposed on the substrate and covering the active device;
a pixel electrode disposed on the planarization layer and electrically connected to the active device; and
a patterned protection layer disposed on the planarization layer and laterally surrounding the pixel electrode, wherein both the patterned protection layer and the pixel electrode are in contact with the planarization layer.

2. The pixel structure according to claim 1, wherein the patterned protection layer has an opening, and the pixel electrode overlaps an area of the opening.

3. The pixel structure according to claim 2, wherein an outline of the opening is substantially aligned with an outline of the pixel electrode.

4. The pixel structure according to claim 1, wherein a material of the patterned protection layer comprises an inorganic insulation material.

5. The pixel structure according to claim 1, wherein a material of the patterned protection layer comprises silicon nitride.

6. The pixel structure according to claim 1, wherein the patterned protection layer partially overlaps a periphery of the pixel electrode.

7. The pixel structure according to claim 1, wherein a material of the patterned protection layer comprises an organic insulation material.

8. The pixel structure according to claim 1, wherein the pixel electrode and the patterned protection layer completely cover the planarization layer.

9. The pixel structure according to claim 1, further comprising a functionality layer disposed on the substrate, wherein the functionality layer and the active device are positioned on two opposite sides of the substrate.

10. A manufacturing method of a pixel structure, comprising:
forming an active device on a substrate;
forming a planarization layer on the substrate to cover the active device;
forming a pixel electrode on the planarization layer by using a common photomask; and
forming a patterned protection layer on the planarization layer by using the common photomask, wherein the patterned protection layer laterally surrounds the pixel electrode.

11. The manufacturing method of the pixel structure according to claim 10, wherein a method of forming the pixel electrode comprises:
forming a conductive material layer and a first photoresist layer on the planarization layer;
patterning the first photoresist layer into a first photoresist pattern by using the common photomask; and
patterning the conductive material layer into the pixel electrode by using the first photoresist pattern as a mask.

12. The manufacturing method of the pixel structure according to claim 11, wherein a method of forming the patterned protection layer comprises:
forming an insulation material layer and a second photoresist layer on the planarization layer;
patterning the second photoresist layer into a second photoresist pattern by using the common photomask; and
patterning the insulation material layer into the patterned protection layer by using the second photoresist pattern as a mask.

13. The manufacturing method of the pixel structure according to claim 12, wherein the first photoresist layer is a positive photoresist and the second photoresist layer is a negative photoresist.

14. The manufacturing method of the pixel structure according to claim 11, wherein a method of forming the patterned protection layer comprises:
forming a photosensitive insulation material layer on the planarization layer; and
patterning the photosensitive insulation material layer into the patterned protection layer by using the common photomask.

15. The manufacturing method of the pixel structure according to claim 14, wherein the first photoresist layer is a positive photoresist and the photosensitive insulation material layer is a negative photoresist.

16. The manufacturing method of the pixel structure according to claim 14, wherein the method of forming the patterned protection layer further comprises a baking operation to form a slope on an edge of the patterned protection layer.

17. The manufacturing method of the pixel structure according to claim 10, further comprising forming a functionality layer on the substrate, wherein the functionality layer and the active device are positioned on two opposite sides of the substrate.
